(19) United States
(12) Patent Application Publication
(10) Pub. No.: US 2026/0142126 A1
(43) Pub. Date: May 21, 2026

(54) IMPEDANCE MATCHING CIRCUIT, PLASMA PROCESS SUPPLY SYSTEM AND PLASMA PROCESS SYSTEM

(71) Applicant: TRUMPF Hüttinger GmbH + Co. KG, Freiburg (DE)

(72) Inventors: Birger Nordmann, Herdecke (DE); Florian A. Maier, Pfaffenweiler (DE)

(21) Appl. No.: 19/310,972

(22) Filed: Aug. 27, 2025

Related U.S. Application Data
(63) Continuation of application No. PCT/EP2024/054980, filed on Feb. 27, 2024.

(30) Foreign Application Priority Data
Feb. 28, 2023 (DE) 10 2023 104 948.8

(51) Int. Cl. H01J 37/32

(52) U.S. Cl. CPC H01J 37/32183

(57) ABSTRACT

An impedance matching circuit for powers ≥500 W and frequencies in a range from 2 to 100 MHz for a plasma process supply system and plasma process system, including a first and second impedance matching unit. The first impedance matching unit is configured to perform a first predetermined impedance transformation. The second impedance matching unit is configured to perform a second predetermined impedance transformation with an adjustable transformation ratio. The second impedance matching unit includes a reactance, a semiconductor switching element, and an electrically continuously variable reactance. The first impedance matching unit is configured to perform the first predetermined impedance transformation such that a conductance of an impedance at the input or output of the second impedance matching unit is greater than a conductance of an impedance arising at the input or output of the second impedance matching unit at a rated power.

### CROSS REFERENCE TO RELATED APPLICATIONS

This application is a continuation of International Application No. PCT/EP2024/054980 (WO 2024/180076 A1), filed on Feb. 27, 2024, and claims benefit to German Patent Application No. DE 10 2023 104 948.8, filed on Feb. 28, 2023. The aforementioned applications are hereby incorporated by reference herein.

### FIELD

The invention relates to an impedance matching circuit, a plasma process supply system and a plasma process system.

### BACKGROUND

An impedance matching circuit can be used in systems in which a load is supplied with electrical power, in particular high-frequency power. ‘High frequency’ is also abbreviated to ‘HF’ in the following. HF here refers to frequencies in the range from 2 MHz to 100 MHz, in particular in the range from 10 MHz to 50 MHz.

In such a system, the impedance of the load should be matched to the impedance of the power supply, since otherwise a reflection of power may occur. The reflection of power has a direct impact on the efficiency of a system; it reduces the effectiveness of a system.

An example system in which an impedance matching circuit can be used is a plasma process system.

Such a plasma process system may, for example, be a system in which a load, e.g., a plasma process arrangement, is supplied with electrical power.

Such a plasma process arrangement can, for example, be a plasma process chamber used for industrial plasma processes such as the surface treatment of workpieces, semiconductor manufacturing with plasma or the processing of workpieces with gas lasers.

In such an application, the plasma process arrangement is used to generate plasma.

For this purpose, a plasma process arrangement may comprise an electrode which is fed with a high-frequency power signal for generating the plasma, hereinafter referred to as the HF power signal.

Typically, a high-power and, in particular, high-voltage power supply is required, for which the plasma process arrangement can be connected to a high-frequency power supply, hereinafter referred to as HF power supply.

The plasma process taking place in the plasma process arrangement has the problem that the electrical load impedance of the plasma process arrangement, which occurs during the process, depends on the conditions in the plasma process arrangement and can vary greatly. In particular, the properties of the workpiece, electrode and gas conditions are taken into account.

For this reason, an impedance matching circuit is usually required to transform the impedance of the load to a nominal impedance of the HF power supply. Such an impedance matching circuit is usually placed between an HF power supply and the plasma process arrangement, usually in the immediate vicinity of the plasma process arrangement.

An impedance matching circuit is usually an arrangement that can have inductors and/or capacitors.

For complex problems where it is important to be able to change the impedance quickly, semiconductor-switched impedance matching circuits are often used. These semiconductor switching elements can be used to connect and disconnect inductors and/or capacitors in impedance matching circuits. Control circuits can be used to control the connecting and disconnecting by the semiconductor switching elements. An example of such a semiconductor-switched impedance matching circuit is disclosed and described in DE 20 2020 102 084 U1.

Such semiconductor-switched impedance matching circuits inherently have only a discrete set of possible output impedances at a given frequency. However, the finest possible adjustment is desirable. This would require a relatively large number of semiconductor switches. However, this is inconsistent with the need for a design that is as compact as possible. A design that is as compact as possible is generally desired, since space in such a plasma process system is often limited.

### SUMMARY

In an embodiment, the present disclosure provides an impedance matching circuit for powers ≥500 W and frequencies in a range from 2 to 100 MHz for a plasma process supply system and plasma process system, comprising a first impedance matching unit and a second impedance matching unit. The first impedance matching unit comprises one or more reactances, the first impedance matching unit being configured to perform a first predetermined impedance transformation from an input terminal of the first impedance matching unit to an output of the first impedance matching unit. The second impedance matching unit is configured to perform a second predetermined impedance transformation with an adjustable transformation ratio from an input terminal of the second impedance matching unit to an output terminal of the second impedance matching unit. The second impedance matching unit comprises one or more reactances, a semiconductor switching element, the adjustable transformation ratio being variable in predetermined steps by the semiconductor switching element during operation, and an electrically continuously variable reactance, the adjustable transformation ratio being steplessly variable during operation by the electrically continuously variable reactance. The semiconductor switching element and/or the electrically continuously variable reactance is/are configured to be operable up to a maximum permissible voltage and a maximum permissible current. The first impedance matching unit is configured to perform the first predetermined impedance transformation such that a conductance of an impedance at the input or output of the second impedance matching unit is greater than a conductance of an impedance that would arise at the input or output of the second impedance matching unit at a rated power of the impedance matching unit and a maximum permissible voltage of the at least one semiconductor switching element and/or the electrically continuously variable reactance. The first impedance matching unit is also configured to perform the first predetermined impedance transformation such that a resistance of the impedance at the input or output of the second impedance matching unit is greater than a resistance of the impedance which would arise at the input or output of the second impedance matching unit at the rated power and the maximum permissible current of the at least one semiconductor switching element and/or the electrically continuously variable reactance.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 illustrates a schematic view of an embodiment of a plasma process system with an impedance matching circuit according to the present disclosure;

FIG. 2a and FIG. 2b illustrate embodiments of a first impedance matching unit of an impedance matching circuit according to the present disclosure;

FIG. 3a, FIG. 3b, FIG. 3c, FIG. 3d, FIG. 3e and FIG. 3f illustrate embodiments of a second impedance matching unit of an impedance matching circuit according to the present disclosure;

FIG. 4a, FIG. 4b, FIG. 4c and FIG. 4d illustrate embodiments of electrically continuously variable reactances;

FIG. 5 illustrates an embodiment of a measuring unit of a plasma process supply system; and

FIG. 6 illustrates a part of a measuring unit of a plasma process system.

### DETAILED DESCRIPTION

In an embodiment, the present disclosure provides an impedance matching circuit which increases the number of possible output impedances and enables a continuously variable output impedance at least for one range, as well as making more advantageous use of the components used and thus enabling a compact design.

According to the present disclosure, an impedance matching circuit for powers ≥500 W, preferably ≥2 kW and frequencies in the range from 2 MHz to 100 MHz, in particular in the range from 10 MHz to 50 MHz, is proposed, in particular for a plasma process supply system and a plasma process system, comprising:
a) a first impedance matching unit comprising one or more reactances, which is designed to perform a first predetermined impedance transformation from its input terminal to its output,
b) a second impedance matching unit, which is designed to perform a second predetermined impedance transformation with an adjustable transformation ratio from its input terminal to its output, the second impedance matching unit comprising:
   i) one or more reactances and
   ii) a semiconductor switching element, with it being provided to vary the transformation ratio in predetermined steps during operation by the semiconductor switching element, and
   iii) an electrically continuously variable reactance, with it being provided to vary the transformation ratio steplessly during operation by the electrically continuously variable reactance,
c) the semiconductor switching element and/or the electrically continuously variable reactance being operable up to a maximum permissible voltage and a maximum permissible current,
d) wherein the first impedance matching unit is designed to perform the first predetermined impedance transformation in such a way that
   i) the conductance of the impedance at the input or output of the second impedance matching unit is greater than the conductance of the impedance that would arise at the input or output of the second impedance matching unit at the rated power of the impedance matching unit and the maximum permissible voltage of the at least one semiconductor switching element and/or the electrically continuously variable reactance; and
   ii) the resistance of the impedance at the input or output of the second impedance matching unit is greater than the resistance of the impedance that would be arise at the input or output of the second impedance matching unit at the rated power and the maximum permissible current of the at least one semiconductor switching element and/or the electrically continuously variable reactance.

As mentioned above, a semiconductor-switched impedance matching circuit has only a discrete set of possible output impedances. If the design of the impedance matching circuit is to be as compact as possible, it is important to keep the number of semiconductor switching elements low. On the one hand, this means that these semiconductor switching elements should not be built from parallel connections and/or series connections of a plurality of switching components.

Secondly, this means that the steps between the adjustable values can be quite large.

Owing to all these limitations, the reflection factor cannot be trimmed to zero for all plasma impedance values, since, with the available discrete impedances, not every complex impedance can be converted such that the reflection factor becomes zero. However, the reflected power is a common measure for the quality of power matching in plasma applications. Getting this to zero is therefore often necessary for the acceptance of a product in this market.

In addition, semiconductor-switched impedance matching circuits have the problem that, depending on the load condition, the current and voltage carrying capacity of the semiconductor switches is insufficient. The current and voltage carrying capacity of the actual semiconductor switches determines the maximum transferable power of such an impedance matching circuit. It has been shown that neither in a 50-ohm system nor directly at the plasma process chamber are the impedances suitable to make use of both the current and the voltage limit of a semiconductor switching element in two switching positions. In principle, it can be stated that the semiconductor switching elements are not switched in their optimal range.

Either the current and/or voltage are too low, so the semiconductor switching elements are not fully controlled, or the current and voltage are so high that the semiconductor switching elements can be damaged. The latter case is to be avoided, so in the prior art the semiconductor switches are never fully utilized.

The dimensioning of the impedance matching circuit according to the present disclosure, which was determined by calculations, simulations, circuit design, tests and investigations, ensures that the at least one semiconductor switching element is fully utilized, but is not overloaded. It has been found that the impedance matching unit must meet the above-mentioned criteria regarding the transformation of the input impedance to an intermediate impedance, with the input impedance being preferably constant and more preferably corresponding to 50 ohms. This and the maximum permissible voltage and current of the semiconductor switching element allow the transformation ratio set by the first impedance matching unit to be accurately calculated. The at least one semiconductor switching element is not overloaded, but switches currents and voltages that are below the maximum permissible values. This means that the at least one semiconductor switching element is fully controlled, which in turn means that the semiconductor switching element does not have to be overdimensioned, which in turn reduces costs. The dimensioning rule ensures that no critical situations arise with regard to the current-carrying capacity and dielectric strength of the at least one semiconductor switching element. In the impedance matching circuit according to the present disclosure, it is particularly made possible to dispense with connecting a plurality of semiconductor switching elements in parallel and/or in series with one another. This is advantageous because the effort required to actually switch the plurality of semiconductor switching elements at the same time would be very high. If one semiconductor switching element switches slightly later than the other semiconductor switching elements, this can lead to the destruction of the impedance matching circuit. However, this is successfully avoided by the dimensioning according to the present disclosure. The dimensioning ensures that, at a defined input impedance predetermined in particular by the HF power supply, no operating situation arises for the at least one semiconductor switching element in which the at least one semiconductor switching element could be destroyed. The at least one semiconductor switching element only has to switch currents and/or voltages that are below the maximum permissible voltage and/or the maximum permissible current. An additional control loop to measure voltages and/or currents and to make the switching behavior dependent on them is therefore not necessary. As a result, the semiconductor switching element does not have to be significantly overdimensioned as in impedance matching circuits from the prior art, which makes the impedance matching circuit according to the present disclosure cheaper to manufacture.

For the term “conductance” of a complex impedance Z, generally the conductance should be real and equal to G, with the following relationship: Z=1/Y=1/(G+jB).

The conductance of the intermediate impedance Z₁ is therefore G₁, where:

$${\underline{Z}}_{1} = 1 / {\underline{Y}}_{1} = 1 / ( {G}_{1} + {jB}_{1} ) .$$

The conductance of the output impedance Z_{P} is therefore G_{P}, where:

$${\underline{Z}}_{P} = 1 / {\underline{Y}}_{P} = 1 / ( {G}_{P} + {jB}_{P} ) .$$

B, B₁, B_{P} is the imaginary part of the complex conductance Y, Y₁, Y_{P}.

For the term “resistance” of a complex impedance Z, generally the resistance should be real and equal to R, with the following relationship: Z=R+jX.

The resistance of the intermediate impedance Z₁ is therefore R₁ where:

$${\underline{Z}}_{1} = {R}_{1} + {jX}_{1} .$$

The resistance of the output impedance Z_{P} is therefore R_{P}, where:

$${\underline{Z}}_{P} = {R}_{P} + {jX}_{P} .$$

X, X₁, X_{P} is the imaginary part of the complex impedance Z, Z, Z_{P}.

In an embodiment, the first impedance matching unit is designed such that the conductance of the impedance at the input of the second impedance matching unit is greater than the conductance of the impedance that would arise at the input of the second impedance matching unit at the rated power of the impedance matching unit and the maximum permissible voltage of the at least one semiconductor switching element and/or the electrically continuously variable reactance; and the resistance of the impedance at the input of the second impedance matching unit is greater than the resistance of the impedance that would arise at the input of the second impedance matching unit at the rated power and the maximum permissible current of the at least one semiconductor switching element and/or the electrically continuously variable reactance.

By using an electrically continuously variable reactance in the impedance matching circuit, the number of possible output impedances can be increased and a steplessly variable output impedance can be achieved at least for a certain range.

The upper end of this certain range can advantageously be limited by the impedance of the impedance matching circuit without the electrically continuously variable reactance added to the largest possible impedance of the electrically continuously variable reactance. The lower end of the range can advantageously be limited by the impedance of the impedance matching circuit without the electrically continuously variable reactance added to the smallest possible impedance of the electrically continuously variable reactance.

The largest and smallest possible impedance of the electrically continuously variable reactance depends on the component. The electrically continuously variable reactance can be steplessly adjusted between these two limits. The impedance can be adjusted, for example, by applying a control voltage.

The electrically continuously variable reactance can be implemented as either an electrically continuously variable capacitor or an electrically continuously variable inductor. An electrically continuously variable capacitor can be, for example, a varactor. An electrically continuously variable inductor can be, for example, a transducer. A transducer is understood here to mean an electromagnetic component for controlling alternating currents by electrical signals, in particular direct currents, in particular by pre-magnetizing the magnetic core of a choke.

In an embodiment of the impedance matching circuit, the input impedance is substantially constant and equal to the predetermined target input impedance during operation of the impedance matching circuit. On the one hand, this presents a constant impedance to the HF power supply and, on the other hand, the constant transformation ratio of the input impedance to the intermediate impedance by the first impedance matching unit ensures that the at least one semiconductor switching element is always operated within tolerances and at the same time with a high level of modulation.

In an embodiment, the first impedance matching unit of the impedance matching circuit can be implemented with exclusively fixed reactances. Such an implementation is cost-effective and robust.

In an embodiment, the impedance matching unit can have a plurality of semiconductor switching elements and one, in particular a plurality of, control circuit(s) respectively associated with these semiconductor switching elements, wherein the semiconductor switching elements are each designed to connect and disconnect reactances. This allows a wide range of impedance matching to be covered and at the same time a compact design to be achieved.

In an embodiment, the at least one semiconductor switching element of the second impedance matching unit can be a transistor or a diode. This allows the transformation ratio to be changed particularly quickly during operation.

A transistor can be designed as a metal-oxide-semiconductor field-effect transistor (MOSFET). A switching diode can, for example, be designed as a PIN diode.

The at least one semiconductor switching element can also be cooled by a fluid. The fluid can be water, for example. This also includes distilled water. For cooling purposes, the semiconductor switching element can be arranged on a cooling body. This cooling body can be made of metal in particular, e.g., aluminum and/or copper. The cooling body can further comprise at least one channel through which the fluid can flow and dissipate the heat of the semiconductor switching element.

In an embodiment, the impedance matching circuit can be used in a plasma process supply system or a plasma process system.

Such a plasma process supply system can include, in addition to the impedance matching circuit, an HF power supply for providing the HF power signal. The impedance matching circuit can be electrically connected to the HF power supply and can be designed to be connected to a plasma process arrangement.

In a plasma process system, such a plasma process arrangement can be present and connected to the plasma process supply system. The plasma process arrangement can be supplied with power from the HF power signal via the plasma process supply system.

Embodiments of the present disclosure are shown schematically in the drawings and are explained in more detail below with reference to the figures.

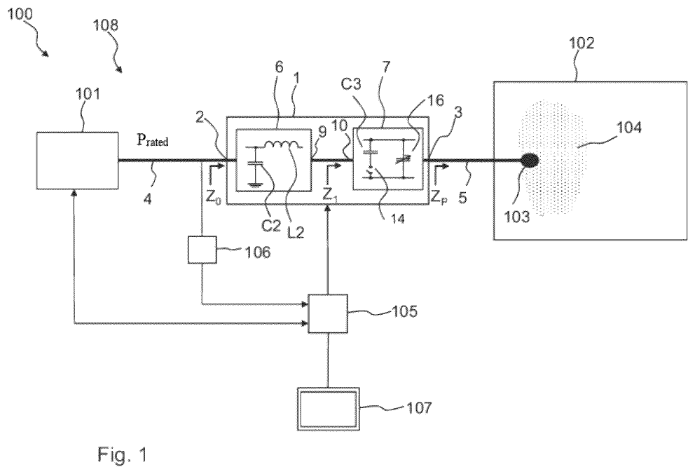

FIG. 1 shows a plasma process system 100 comprising a plasma process supply system 108. The plasma process supply system 108 comprises an impedance matching circuit 1 according to the present disclosure and an HF power supply 101. The plasma process supply system 108 is designed to be connected to at least one consumer 102, in particular a plasma process arrangement, e.g., in the form of a plasma process chamber. If the plasma process supply system 108 is connected to a described consumer 102 as shown in FIG. 1, it is supplemented to form a plasma process system 100. The HF power supply 101 is designed to provide an HF signal, in particular in the form of a uniform signal, also called a continuous wave signal, or a CW signal for short, with a rated power Prated. The impedance matching circuit 1 comprises an input terminal 2, with the HF power supply 101 being connected to the input terminal 2. The impedance matching circuit 1 further comprises an output terminal 3.

The output terminal 3 is connected to the at least one consumer 102. The HF power supply 101 is preferably connected to the impedance matching circuit 1 via a first cable arrangement 4. The impedance matching circuit 1 is preferably connected to the consumer 102 via a second cable arrangement 5. The first and/or second cable arrangement 4, 5 can comprise one or more cables, for example connected in series and/or in parallel. Coaxial cables are preferably used.

The consumer 102, in this case the plasma process arrangement in the form of a plasma process chamber, comprises at least one electrode 103 for generating a plasma 104. The electrode 103 is connected to the output terminal 3 of the impedance matching circuit 1.

The plasma process supply system 108 also comprises a control and/or detection device 105. This can preferably comprise a processor and/or a programmable logic component, in particular an FPGA and/or microcontroller and/or a preconfigured logic component, in particular an ASIC. The control and/or detection device 105 can also comprise a memory unit. The control and/or detection device 105 is designed to control the HF power supply 101, in particular to activate or deactivate it. Additionally or alternatively, the control and/or detection device 105 is also designed to change the power and/or frequency of the HF signal. Additionally or alternatively, the control and/or detection device 105 is designed to change the waveform, in particular the type of the HF signal or modulation of the HF signal.

The control and/or detection device 105 is preferably also designed to control the impedance matching circuit 1. In particular, the control and/or detection device 105 is designed to change the transformation ratio within the impedance matching circuit 1.

Preferably, the plasma process supply system 108 also comprises a measuring unit 106. The measuring unit 106 is arranged between the HF power supply 101 and impedance matching circuit 1. The measuring unit 106 can, for example, comprise at least one directional coupler or a current sensor and a voltage sensor. Via the at least one directional coupler, the measuring unit 106 can measure the power of the HF signal which is transmitted from the HF power supply 101 towards the impedance matching circuit 1. Preferably, the measuring unit 106 can also measure the power of an HF signal which is reflected at the impedance matching circuit 1 back towards the HF power supply 101. The power of the HF signal transmitted from the HF power supply 101 towards the impedance matching circuit I can also be determined via the current sensor and the voltage sensor. A power of an HF signal reflected by the impedance matching circuit 1 can also be detected by the current sensor and the voltage sensor.

The plasma process supply system 108 preferably also comprises an operating unit 107. The operating unit 107 preferably has a screen, in particular a touch-sensitive screen. In addition to a screen, the operating unit 107 can also comprise input means such as a keyboard and/or mouse. The operating unit 107 can also be a web server that provides data and receives user input. The control and/or detection device 105 is designed to display current settings of the HF power supply 101 and/or the impedance matching circuit 1 on the operating unit 107. The control and/or detection device 105 can also be designed to display the measurement values received by the measuring unit 106 on the operating unit 107. The control and/or detection device 105 is preferably designed to receive setpoint specifications, for example for the power of the HF signal, the frequency of the HF signal and/or the waveform of the HF signal, from the operating unit 107 and to generate corresponding manipulated variables for the HF power supply 101 and to transmit them to the latter.

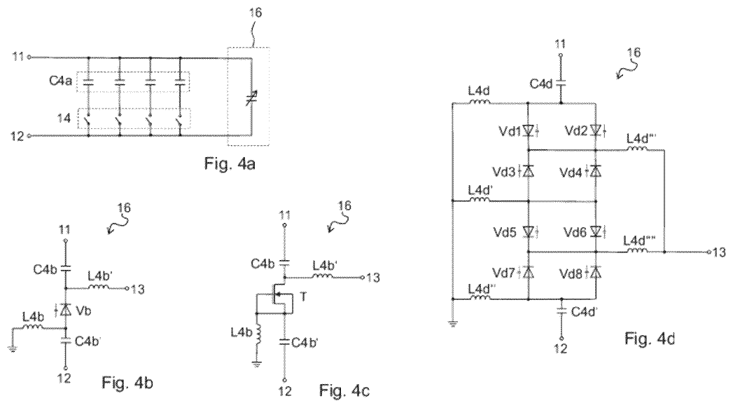

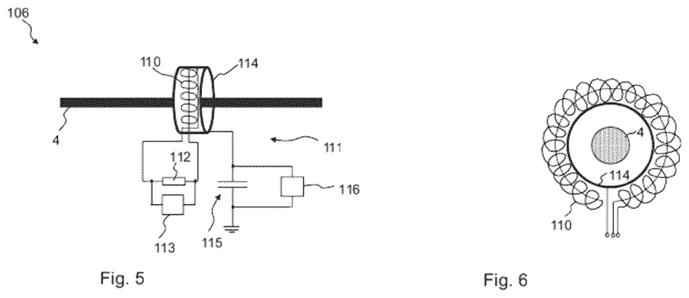

Before the impedance matching circuit I according to the present disclosure is explained in detail, reference is made to FIGS. 5 and 6, which describe the measuring unit 106. In this exemplary embodiment, the measuring unit 106 is designed to measure a voltage and a current without contact. For this purpose, the measuring unit 106 comprises a current sensor 110 and a voltage sensor 111. These are shown in detail in FIG. 5 and FIG. 6.

Preferably, however, the phase relationship between current and voltage is still measured.

The current sensor 110 of the measuring unit 106 is a coil, in particular in the form of a Rogowski coil.

Both ends of the coil are preferably connected to each other via a shunt resistor 112. The voltage which drops across the shunt resistor 112 can be digitized by means of a first A/D converter 113.

The voltage sensor 111 of the measuring unit 106 is preferably built as a capacitive voltage divider. A first capacitor 114 is formed by an electrically conductive ring 114. An electrically conductive cylinder could also be used. The first cable arrangement 4 is guided through this electrically conductive ring 114. A second capacitor 115 of the voltage sensor 111, which is built as a voltage divider, is connected to the reference ground. A second A/D converter 116 is connected in parallel to the second capacitor 115 and is designed to detect and digitize the voltage which drops across the second capacitor 115.

In principle, the measuring unit 106 can also be arranged or built on a (common) circuit board. The first capacitor 114 can be formed by a coating on a first and an opposite second side of the circuit board. In this case, the coatings on the first side and the second side are electrically connected to each other by vias. The first cable arrangement 4 is guided through an opening in the circuit board. The second capacitor 115 can be formed by a discrete component.

The current sensor 110 in the form of the coil, in particular in the form of the Rogowski coil, is further spaced apart from the first cable arrangement 4 than the first capacitor 114. The coil can also be formed on the same circuit board by corresponding coatings and vias. The coil for current measurement and the first capacitor for voltage measurement preferably run through a common plane.

The shunt resistor 112 can also be arranged on this circuit board. The same applies to the first and/or second A/D converter 113, 116. The first and/or second A/D converter 113, 116 is read and/or controlled by the control and/or detection device 105.

The control and/or detection device 105 is preferably designed to control the impedance matching circuit 1 on the basis of the measurement values of the measuring unit 106.

In the following, reference is again made to FIG. 1 and the structure of the impedance matching circuit 1 is explained in more detail. The impedance matching circuit 1 comprises a first impedance matching unit 6 and a second impedance matching unit 7. The first impedance matching unit 6 is electrically connected to the input terminal 2.

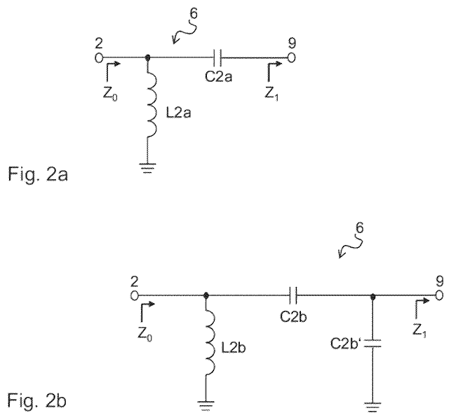

The first impedance matching unit 6 is designed to transform an input impedance Z₀, which is applied to input terminal 2, to an intermediate impedance Z₁. The intermediate impedance Z₁ is applied to an output 9 of the first impedance matching unit 6. The transformation ratio is unchangeable during operation. In FIG. 1, the first impedance matching unit 6 has an inductor L2 and a capacitor C2 which are connected in an L-shape. Many other designs are conceivable, and some more are shown by way of example in FIG. 2a and FIG. 2b. The second impedance matching unit 7 is connected to the first impedance matching unit 6 in the transmission direction of the HF signal from the HF power supply 101 to the consumer 102. In particular, the second impedance matching unit 7 comprises an input 10 which is connected to the output terminal 9 of the first impedance matching unit 6 or which is directly connected to the output 9. There is therefore also the intermediate impedance Z₁ at the input 10. The second impedance matching unit 7 is designed to transform the intermediate impedance Z₁ at its input 10 to an output impedance Z_{P} at the output terminal 3, and the transformation ratio can be varied during operation by at least one semiconductor switching element 14. The second impedance matching unit 7 in FIG. 1 has, by way of example, an electrically continuously variable reactance 16 which is connected in parallel to a series connection consisting of a capacitor C3 and a semiconductor switching element 14.

The at least one semiconductor switching element 14 of the second impedance matching unit 7 can be operated up to a maximum permissible voltage and up to a maximum permissible current. The intermediate impedance Z₁ to which the first impedance matching unit 6 transforms the input impedance Z₀ is chosen for a predetermined target input impedance such that:
a) the conductance G₁ of the intermediate impedance Z₁ is greater than the conductance of the impedance which would arise at the input 10 of the second impedance matching unit 7 at the rated power P_{rated} of the impedance matching circuit 1 and the maximum permissible voltage of the at least one semiconductor switching element 14; and
b) the resistance R₁ of the intermediate impedance Z₁ is greater than the resistance of the impedance which would arise at the input 10 of the second impedance matching unit 7 at the rated power P_{rated} and the maximum permissible current of the at least one semiconductor switching element 14.

The rated power P_{rated} of the impedance matching circuit 1 is preferably identical to the rated power P_{rated} of the HF power supply 101.

A transmission path for transmitting the HF signal runs between the input terminal 2 and the output terminal 3 of the impedance matching circuit 1. The first and second impedance matching units 6, 7 are arranged in the transmission path.

An exemplary structure of the first and second impedance matching units 6, 7 of the impedance matching circuit 1 is explained in more detail in the following figures.

FIGS. 2a and 2b show two different circuit diagrams of the first impedance matching unit 6, which in these exemplary embodiments do not have a semiconductor switching element 14.

FIG. 2a shows an embodiment of the first impedance matching unit 6 in an L-shape, which has an inductor L2a and a capacitor C2a. The inductor L2a is connected from the input terminal 2 to ground. The capacitor C2a is connected between the input terminal 2 and the output 9 of the first impedance matching unit 6. This first impedance matching unit 6 is designed to transform the input impedance Z₀ at the input terminal 2 to an intermediate impedance Z₁ at its output 9.

FIG. 2b shows an embodiment for the first impedance matching unit 6 in a x-shape, which has an inductor L2b and two capacitors C2b, C2b′. The inductor L2b is connected from the input terminal 2 to ground. The capacitor C2b is connected between the input terminal 2 and the output 9 of the first impedance matching unit 6. The capacitor C2b′ is connected from the output 9 to ground.

This first impedance matching unit 6 is designed to transform the input impedance Z₀ at the input terminal 2 to an intermediate impedance Z₁ at its output 9.

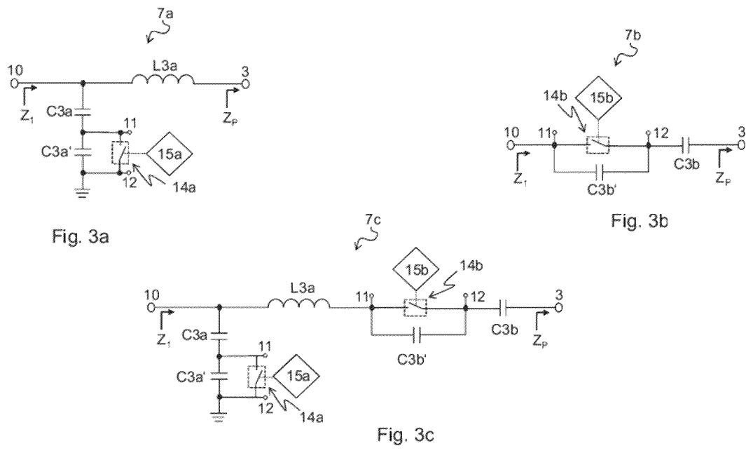

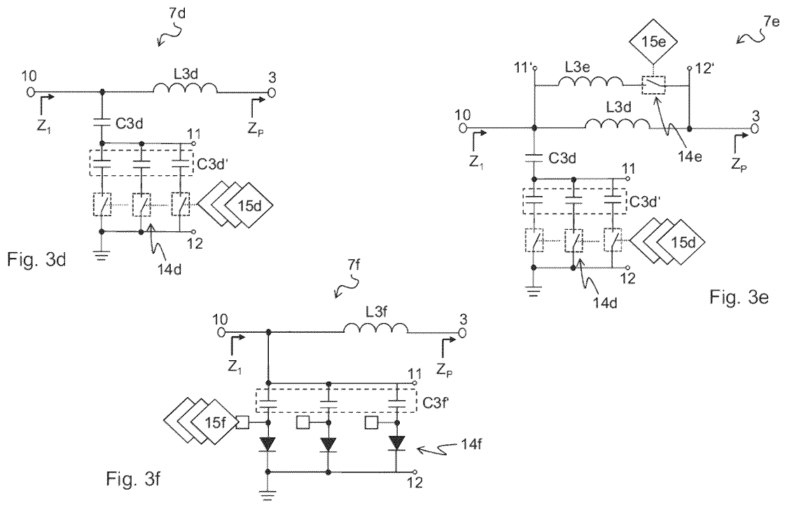

FIGS. 3a to f show various circuit diagrams of the second impedance matching unit 7a-7f, which in these exemplary embodiments is designed with one or more semiconductor switching elements 14a-14f and one or more control circuits 15a-15f. The second impedance matching units 7a-7f further comprise a first terminal 11 and a second terminal 12, to which an electrically continuously variable reactance 16 is connected (shown in FIGS. 4b to 4d). Embodiments and functions of this electrically continuously variable reactance 16 are discussed in more detail in the descriptions of FIGS. 4a to 4d.

FIG. 3a shows an embodiment of the second impedance matching unit 7a in an L-shape, which has an inductor L3a and two capacitors C3a, C3a′. The inductor L3a is connected between the input 10 and the output terminal 3. The capacitors C3a, C3a′ are connected in series and this series connection is connected from the input 10 to ground. The capacitor C3a′ is connected directly to ground. A semiconductor switching element 14a is connected in parallel to the capacitor C3a′. An electrically continuously variable reactance 16 (shown in FIGS. 4a to d) is also connected in parallel to the capacitor C3a′ and the semiconductor switching element 14a.

The semiconductor switching element 14a is connected to a control circuit 15a which is configured to switch the semiconductor switching element 14a on and off. When the semiconductor switching element 14a is switched on, the capacitor C3a′ and the electrically continuously variable reactance 16 are short-circuited and the resulting capacitance of the series connection is equal to the capacitor C3a. When the semiconductor switching element 14a is turned off, the capacitor C3a′ is not short-circuited and the resulting impedance of the series connection is equal to that of a series connection of the capacitor C3a and the parallel connection of the capacitor C3a′ and the electrically continuously variable reactance 16.

This second impedance matching unit 7a is designed to transform the intermediate impedance Z₁ at its input 10 to an output impedance Z_{P} at the output terminal 3, and the transformation ratio can be varied during operation by the semiconductor switching element 14a and the electrically continuously variable reactance 16.

FIG. 3b shows an embodiment for the second impedance matching unit 7b, which has two capacitors C3b, C3b′. The capacitor C3b is connected in series with a semiconductor switching element 14b. This series connection consisting of capacitor C3b and semiconductor switching element 14b is connected between the input 10 and the output terminal 3. The capacitor C3b′ is connected in parallel to the semiconductor switching element 14b. Furthermore, an electrically continuous reactance 16 (shown in FIGS. 4a to d) is connected in parallel to the capacitor C3b′ and the semiconductor switching element 14b via the two terminals 11, 12. The semiconductor switching element 14b is connected to a control circuit 15b which is configured to switch the semiconductor switching element 14b on and off. When the semiconductor switching element 14b is turned on, the capacitor C3b′ and the electrically continuously variable reactance 16 are short-circuited and the resulting capacitor of the second impedance matching unit 7b is equal to the capacitor C3b. When the semiconductor switching element 14b is switched off, the capacitor C3b′ is not short-circuited and the resulting impedance of the second impedance matching unit 7b is equal to that of a series connection of the capacitor C3b and the parallel connection of the capacitor C3b′ and the electrically continuously variable reactance 16.

This second impedance matching unit 7b is designed to transform the intermediate impedance Z₁ at its input 10 to an output impedance Z_{P} at the output terminal 3, wherein the transformation ratio can be varied during operation by the semiconductor switching element 14b and the electrically continuously variable reactance 16.

FIG. 3c shows an embodiment for the second impedance matching unit 7c, which comprises a series connection of the two second impedance matching units 7a, 7b from FIG. 3a and FIG. 3b. This series connection is connected between the input 10 and the output terminal 3. The function of the second impedance matching unit 7c, i.e., the series connection of the two second impedance matching units 7a, 7b, follows from the functions of the individual impedance matching units 7a, 7b described in the descriptions of FIG. 3a and FIG. 3b only when combined as a series connection.

This second impedance matching unit 7c is designed to transform the intermediate impedance Z₁ at its input 10 to an output impedance Z_{P} at the output terminal 3, and the transformation ratio can be varied during operation by the semiconductor switching elements 14a, 14b and the electrically continuously variable reactance 16.

FIG. 3d shows an embodiment for the second impedance matching unit 7d in an L-shape, which has an inductor L3d, a capacitor C3d and three further capacitors C3d′ and three semiconductor switching elements 14d. The inductor L3d is connected between the input 10 and the output terminal 3. The capacitor C3d is connected in series with a parallel connection consisting of the three further capacitors C3d′ and the three semiconductor switching elements 14d. This parallel connection has three parallel-connected series connections consisting of a capacitor C3d′ and a semiconductor switching element 14d as well as an electrically continuously variable reactance 16 connected in parallel thereto (shown in FIGS. 4a to d). Each semiconductor switching element 14d is connected to a control circuit 15d which is configured to switch the semiconductor switching elements 14d on and off. When one of the three semiconductor switching elements 14d is switched on, the capacitor C3d is connected in series with the parallel connection of one of the three capacitors C3d′ and the electrically continuously variable reactance 16. This series connection is connected from the input 15 to ground. If one or both of the further semiconductor switching elements 14d are also switched on, the capacitor C3d is connected in series with a parallel connection of two or three of the capacitors C3d′ and the electrically continuously variable reactance 16. This parallel connection can be extended by further parallel-connected series connections, but can also have only two parallel-connected series connections and the electrically continuously variable reactance 16. When all semiconductor switching elements 14d are switched off, a series connection results from the capacitor C3d and the electrically continuously variable reactance 16. This series connection is connected from the input 10 to ground.

This second impedance matching unit 7d is designed to transform the intermediate impedance Z₁ at its input 10 to an output impedance Z_{P} at the output terminal 3, and the transformation ratio can be changed during operation by the semiconductor switching elements 14d and the electrically continuously variable reactance 16.

FIG. 3e shows an embodiment for the second impedance matching unit 7e in an L-shape, which comprises the second impedance matching unit 7d from FIG. 3d. In addition to the second impedance matching unit 7d described in the description of FIG. 3d, this second impedance matching unit 7e here has an additional inductor L3e, an additional semiconductor switching element 14e, additional terminals 11′, 12′ for an electrically continuously variable reactance and an additional electrically continuously variable reactance 16. The inductor L3e is connected in series with the semiconductor switching element 14e. The series connection is connected in parallel to the inductor L3d. Furthermore, the additional electrically continuously variable capacitor 16 is connected in parallel to this series connection and to the inductor L3d. The additional electrically continuously variable reactance 16 is connected to the terminals 11′, 12′.

The semiconductor switching element 14e is connected to a control circuit 15e which is configured to switch the semiconductor switching element 14e on and off. When the semiconductor switching element 14e is switched on, the two inductors L3e, L3d and the additional electrically continuously variable reactance 16 are connected in parallel.

When the semiconductor switching element 14e is switched off, the inductor L3e has no influence on the impedance of the second impedance matching unit 7e and the second impedance matching unit 7e corresponds to the second impedance matching unit 7d of FIG. 3d, wherein the inductor L3d is connected in parallel with the additional electrically continuously variable reactance 16.

This second impedance matching unit 7e is designed to transform the intermediate impedance Z₁ at its input 10 to an output impedance Z_{P} at the output terminal 3, and the transformation ratio can be changed during operation by the semiconductor switching elements 14d, 14e and the electrically continuously variable reactances 16.

FIG. 3f shows an embodiment for the second impedance matching unit 7f in an L-shape, which has an inductor L3f as well as three further capacitors C3f and three semiconductor switching elements 14f. The three semiconductor switching elements 14f are designed as PIN diodes. The inductor L3f is connected between the input 10 and the output terminal 3. The semiconductor switching elements 14f are each connected in series with a capacitor C3f. These three series connections are connected in parallel. An electrically continuously variable reactance 16 is also connected in parallel to these series connections. This entire parallel connection can be extended by further parallel-connected series connections, but can also have only two parallel-connected series connections and an electrically continuously variable reactance. Each semiconductor switching element 14f is connected to a control circuit 15f which is configured to switch the semiconductor switching elements 14f on and off. When one of the three semiconductor switching elements 14f is switched on, one of the three capacitors C3f is connected in parallel with the electrically continuously variable reactance 16. This parallel connection is connected from the input 10 to ground. If one or the other two semiconductor switching elements 14f are also switched on, a parallel connection of two or three capacitors C3f and the electrically continuously variable reactance 16 is connected from the input 10 to ground. When all semiconductor switching elements 14f are switched off, the capacitors C3f have no influence and the electrically continuously variable reactance 16 is switched from the input 10 to ground.

This second impedance matching unit 7f is designed to transform the first intermediate impedance Z₁ at its input 10 to an output impedance Z_{P} at the output terminal 3, and the transformation ratio can be changed during operation by the semiconductor switching elements 14f and the electrically continuously variable reactances 16.

The previously described impedance matching units 6, 7a-7f can be varied, so that instead of capacitors, depending on the desired matching, inductors can be used, or instead of inductors, depending on the desired matching, capacitors can be used.

The previously described impedance matching units 6, 7a-7f can be used individually or in combination of two or more.

FIGS. 4a to 4d show a selection of different embodiments of electrically continuously variable reactances 16. These electrically continuously variable reactances 16 are designed to be connected via the first and second terminals 11, 12 of the second impedance matching unit 7, 7a-7f.

FIG. 4a shows an arrangement in which the electrically continuously variable reactance 16 is connected in parallel to a parallel connection of a plurality of series connections consisting of a capacitor C4a and a semiconductor switching element 14. Such parallel connections are already shown by way of example in FIGS. 3d and 3e.

FIG. 4b shows an embodiment of an electrically continuously variable reactance 16. The electrically continuously variable reactance 16 has a first terminal 11, a second terminal 12, a control terminal 13, two capacitors C4b, C4b′, two inductors L4b, L4b′ and a varactor Vb. The first terminal 11 is connected to the capacitor C4b. The control terminal 13 is connected to the inductor L4b′.

The inductor L4b′ and the capacitor C4b are further connected to each other and to the cathode of the varactor Vb via a node. The anode of the varactor Vb is connected via a node to the capacitor C4b′ and the inductor L4b. The capacitor is further connected to the second terminal 12. The inductor L4b is connected to ground.

The varactor Vb can be used to vary the capacitance by changing the applied voltage.

The two capacitors C4b, C4b′ and the two inductors L4b, L4b′ can be used as HF block filters. For this purpose, the capacitors C4b, C4b′ can be dimensioned such that the capacitor for the connection from the first terminal 11 to the second terminal 12 is determined substantially only by the varactor Vb and at the same time the uniform voltage applied to the control terminal 13 does not affect the first terminal 11 or the second terminal 12. For this purpose, the two inductors L4b, L4b′ can also be dimensioned such that the HF signal which is transmitted from the first terminal 11 to the second terminal 12 does not influence the control which is connected to the control terminal 13 and is only connected to ground via the inductor L4b′ with a very high impedance.

FIG. 4c shows largely the same embodiment of the electrically continuously variable reactance 16 from FIG. 4b. In FIG. 4c, only the varactor Vb is replaced by a transistor T. Using suitable control, in particular by keeping the transistor T off, a variation in the capacitance can also be achieved via this transistor T.

FIG. 4d shows an embodiment of the electrically continuously variable reactance 16. The electrically continuously variable reactance 16 has a first terminal 11, a second terminal 12, a control terminal 13, eight varactors Vd1-Vd8 and five inductors L4d-L4d″″. The varactors Vd1-Vd8 are interconnected in parallel and series connections. By connecting these eight varactors Vd1-Vd8 in different ways, a significantly greater possible variation in capacitance can be achieved than would be the case with a single varactor, for example. The varactors Vd1-Vd8 have the same function as the varactor Vb in FIG. 4b and they could each be replaced by a transistor T, as shown in FIG. 4c. The five inductors L4d-L4d″″ have the same function as the two inductors L4b, L4b′ in FIG. 4b and FIG. 4c. The two capacitors C4d, C4d′ have the same function as the two capacitors C4b, C4b′ in FIG. 4b and FIG. 4c.

With such an arrangement, the HF signal, which is transmitted from the first terminal 11 to the second terminal 12, is distributed among the eight varactors Vd1-Vd8. Thus, the electrically continuously variable reactance 16 can be operated with higher currents and higher voltages. However, it can also be seen how advantageously the condition for the impedance transformation of the first impedance matching unit 6 can be used if it can be used to go from an electrically continuously variable reactance 16 according to FIG. 4d to one according to FIG. 4b or 4c.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. An impedance matching circuit for powers ≥500 W and frequencies in a range from 2 to 100 MHz for a plasma process supply system and plasma process system, comprising:
a) a first impedance matching unit comprising one or more reactances, the first impedance matching unit being configured to perform a first predetermined impedance transformation from an input terminal of the first impedance matching unit to an output of the first impedance matching unit; and
b) a second impedance matching unit configured to perform a second predetermined impedance transformation with an adjustable transformation ratio from an input terminal of the second impedance matching unit to an output terminal of the second impedance matching unit, comprising:
i) one or more reactances,
ii) a semiconductor switching element, the adjustable transformation ratio being variable in predetermined steps by the semiconductor switching element during operation, and
iii) an electrically continuously variable reactance, the adjustable transformation ratio being steplessly variable during operation by the electrically continuously variable reactance,
c) wherein the semiconductor switching element and/or the electrically continuously variable reactance is/are configured to be operable up to a maximum permissible voltage and a maximum permissible current, and
d) wherein the first impedance matching unit is configured to perform the first predetermined impedance transformation such that:
i) a conductance of an impedance at the input or output of the second impedance matching unit is greater than a conductance of an impedance that would arise at the input or output of the second impedance matching unit at a rated power of the impedance matching unit and a maximum permissible voltage of the at least one semiconductor switching element and/or the electrically continuously variable reactance, and
ii) a resistance of the impedance at the input or output of the second impedance matching unit is greater than a resistance of the impedance which would arise at the input or output of the second impedance matching unit at the rated power and the maximum permissible current of the at least one semiconductor switching element and/or the electrically continuously variable reactance.

2. The impedance matching circuit according to claim 1, wherein an input impedance is substantially constant and equal to a predetermined target input impedance during operation of the impedance matching circuit.

3. The impedance matching circuit according to claim 1, wherein the first impedance matching unit is implemented as a first impedance matching unit with exclusively fixed reactances.

4. The impedance matching circuit according to claim 1, comprising a plurality of semiconductor switching elements and a plurality of control circuits respectively associated with the semiconductor switching elements, wherein the semiconductor switching elements are each configured to connect and disconnect reactances.

5. The impedance matching circuit according to claim 1, wherein the at least one semiconductor switching element of the second impedance matching unit is a transistor or a diode.

6. The impedance matching circuit according to claim 1, wherein the semiconductor switching element of the second impedance matching unit is configured to be cooled by a fluid.

7. A plasma process supply system, comprising:
a high frequency (HF) power supply for providing an HF power signal; and
the impedance matching circuit according to claim 1, the impedance matching circuit being electrically connected to the HF power supply and being configured to be connected to a consumer, the consumer being a plasma process arrangement in a form of a plasma process chamber.

8. A plasma process system comprising the plasma process supply system according to claim 7 and a consumer, the consumer being a plasma process arrangement in a form of a plasma process chamber, wherein the consumer is connected to the plasma process supply system and the plasma process supply system is configured to supply the consumer with power of the HF power signal.
